(19) United States
(12) Patent Application Publication
(10) Pub. No.: US 2025/0243577 A1
(43) Pub. Date: Jul. 31, 2025

(54) MOLTEN METAL DISCHARGING DEVICE AND MOLTEN METAL DISCHARGING METHOD

(71) Applicant: Mitsubishi Electric Corporation, Tokyo (JP)

(72) Inventor: Toshiaki IWAO, Tokyo (JP)

(73) Assignee: Mitsubishi Electric Corporation, Tokyo (JP)

(21) Appl. No.: 18/703,443

(22) PCT Filed: Feb. 25, 2022
(86) PCT No.: PCT/JP2022/008026

§ 371 Date: Apr. 22, 2024

(51) Int. Cl. C23C 4/12; C23C 4/08; H01L 23/00

(52) U.S. Cl. CPC C23C 4/12; C23C 4/08; H01L 24/27; H01L 24/74; H01L 2224/27312; H01L 2224/743

(57) ABSTRACT

A syringe (3) includes a storage section (3a) that stores molten metal (1), a discharge nozzle (3b) that discharges the molten metal (1) stored in the storage section (3a), an opening (3c) different from the discharge nozzle (3b), and a bypass path (3d) that connects the opening (3c) and the storage section (3a) and through which the molten metal (1) flows. A heater (5) is provided around the syringe (3) and heating the molten metal (1) to keep it in a molten state. A shaft (4) slides inside the syringe (3) to press the molten metal (1) stored within the storage section (3a). A cover (9) is provided on the opening (3c) and opens and closes. The opening (3c) is positioned above an upper surface of the molten metal (1) inside the syringe (3).

### FIELD

The present disclosure relates to a molten metal discharging device and a molten metal discharging method for discharging molten metal.

### BACKGROUND

Molten metal discharging devices are used, for example, to apply molten metal to the electrodes of semiconductor devices such as Si chips and SiC chips to join them to base plates, lead frames, and the like (see, for example, PTL 1). Typical molten metal discharging devices each include a syringe and a shaft made of glass, for example. The shaft is pulled up with the tip end of the syringe immersed in molten metal, thereby creating a negative pressure in the syringe to draw in the molten metal. Then, the tip end of the syringe is moved to a predetermined position, and then the shaft is pushed down to pressurize the inside of the syringe to discharge the molten metal.

### CITATION LIST

### Patent Literature

[PTL 1] JP 2014-004567 A

### SUMMARY

### Technical Problem

Recent shifts from Si chips to SiC chips and to higher density packaging are leading to smaller semiconductor devices. Smaller semiconductor devices lead to smaller areas of joint portions. On the other hand, in power semiconductor apparatuses and the like, molten metal is used, instead of metal wire bonding, for connecting the main current paths in order to achieve higher currents, longer lives, and higher reliability. In other words, discharging molten metal onto the joint portion on the semiconductor device directly joins the external electrode and the semiconductor device. The smaller area of the joint portion also decreases the amount of molten metal required for each joint portion. In other words, it is required to stabilize the amount of the molten metal to be discharged per discharge operation, that is, the amount of supply per discharge operation, with higher accuracy. The molten metal discharging device discharges molten metal corresponding to the amount of change in volume in the syringe as the shaft moves up and down. Unfortunately, control of the discharge amount has been difficult and the discharge amount per discharge operation has been unstable.

The present disclosure has been made to solve the above-mentioned problem, and an object of the disclosure is to obtain a molten metal discharging device and a molten metal discharging method that can control a discharge amount of molten metal with high accuracy.

### Solution to Problem

A molten metal discharging device according to the present disclosure incudes: a syringe including a storage section that stores molten metal, a discharge nozzle that discharges the molten metal stored in the storage section, an opening different from the discharge nozzle, and a bypass path that connects the opening and the storage section and through which the molten metal flows; a heater provided around the syringe and heating the molten metal to keep the molten metal in a molten state: a shaft sliding inside the syringe to press the molten metal stored within the storage section; and a cover provided on the opening, opening and closing, wherein the opening is positioned above an upper surface of the molten metal inside the syringe.

### Advantageous Effects of Invention

In the present disclosure, a bypass path is provided that connects the opening, which is different from the discharge nozzle, and the storage section. Opening the cover provided at the opening in the molten metal discharge operation allows a certain amount of the molten metal to flow into the bypass path while discharging the molten metal from the discharge nozzle. This makes it possible to discharge the molten metal with a volume smaller than the amount of change in volume in the syringe due to the downward movement of the shaft, to control the discharge amount of the molten metal with high accuracy.

### BRIEF DESCRIPTION OF THE DRAWINGS

FIG. 1 is a cross sectional view showing molten metal suction operation of a molten metal discharging device according to Embodiment 1.

FIG. 2 is a cross sectional view showing the molten metal discharge operation of the molten metal discharging device according to Embodiment 1.

FIG. 3 is a cross sectional view showing the molten metal suction operation of the molten metal discharging device according to Embodiment 2.

FIG. 4 is a cross sectional view showing the molten metal discharge operation of the molten metal discharging device according to Embodiment 2.

### DESCRIPTION OF EMBODIMENTS

A molten metal discharging device and a molten metal discharging method according to the embodiments of the present disclosure will be described with reference to the drawings. The same components will be denoted by the same symbols, and the repeated description thereof may be omitted.

### Embodiment 1

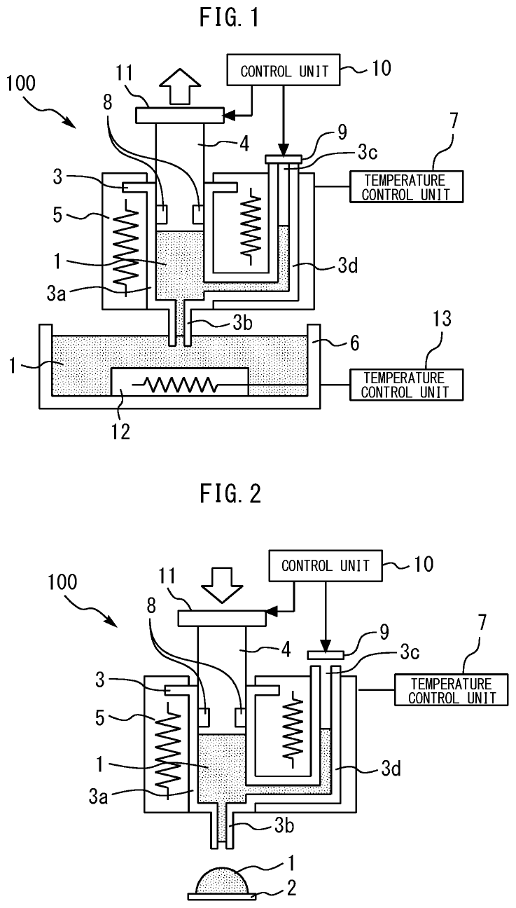

FIG. 1 is a cross sectional view showing molten metal suction operation of a molten metal discharging device according to Embodiment 1. FIG. 2 is a cross sectional view showing the molten metal discharge operation of the molten metal discharging device according to Embodiment 1. A molten metal discharging device 100 discharges molten metal 1 to a joint portion of a component 2. The discharged molten metal 1 joins the component 2 and other members such as a lead frame. The molten metal 1 is, for example, a solder material that has Sn, Pb, or the like as a main component and contains an additive element such as Ag or Cu.

The component 2 may be, for example, an IGBT, diode, or reverse conducting IGBT made of silicon (Si), may be a MOSFET or a Schottky diode made of a material with a larger band gap than Si, such as silicon carbide (SiC) or gallium nitride (GaN), or may be merely a metal lead frame made of copper or the like or a circuit pattern on an insulating substrate for circuit formation. The semiconductor device and the metal lead frame may be joined by positioning a metal lead frame with a hole on top of the semiconductor device and discharging the molten metal 1 through the hole.

The molten metal discharging device 100 includes a syringe 3, a shaft 4, and a heater 5. Note that the molten metal discharging device 100 includes a movement mechanism (not shown) with three-axis of X, Y, and Z that are orthogonal to each other, for reciprocating between a molten metal storage tank 6 and the component 2.

The syringe 3 includes a storage section 3a that stores the molten metal 1, a discharge nozzle 3b that discharges the molten metal 1 stored in the storage section 3a, an opening 3c different from the discharge nozzle 3b, and a bypass path 3d that connects the opening 3c and the storage section 3a and through which the molten metal 1 flows. The opening 3c is positioned above the upper surface of the molten metal 1 inside the syringe 3. The material of the syringe 3 is preferably a material to which the molten metal 1 is not diffusion-bonded, such as glass or ceramic, but is not limited thereto.

The heater 5 is provided around the syringe 3, and heats the molten metal 1 inside the syringe 3 to keep it in a molten state. A temperature control unit 7 controls the heater 5 to maintain the molten metal 1 at a temperature equal to or higher than its melting point. The heater 5 may heat the molten metal 1 by radiation, induction heating, convection heat transfer, or the like.

The shaft 4 slides inside the syringe 3 to press the molten metal 1 stored within the storage section 3a. The shaft 4 has a seal portion 8 for insulating the molten metal 1 within the syringe 3 from outside air. A cover 9 is provided on the opening 3c.

The control unit 10 controls a drive unit 11 to slide the shaft 4 up and down, and controls another drive unit to open and close the cover 9. The control unit 10 can individually control the sliding of the shaft 4, and the opening and closing of the cover 9. The drive unit 11 includes mechanisms such as an actuator, an air cylinder, and a single-axis robot.

When the cover 9 is closed, the bypass path 3d is isolated from outside air. Only when the cover 9 is open, outside air can enter and exit the bypass path 3d. The cover 9 may be an object that can be controlled to open and close, such as an air cylinder or an actuator, or an on-off valve such as a general gate valve or a butterfly valve. Note that a case is shown in which there is one bypass path 3d, but a plurality of bypass paths 3d may be provided for one syringe 3.

The molten metal 1 within the syringe 3 is drawn in from the molten metal storage tank 6. A heater 12 is provided around the molten metal storage tank 6, and heats the molten metal 1 within the molten metal storage tank 6 to keep it in a molten state. A temperature control unit 13 controls the heater 12 to maintain the molten metal 1 at a temperature equal to or higher than its melting point. In order to prevent the surface of the molten metal 1 from being oxidized, the entire molten metal storage tank 6 is preferably positioned in an atmosphere such as an inert gas.

The following describes the molten metal suction operation and molten metal discharge operation of the molten metal discharging device 100 according to the present embodiment.

First, as shown in FIG. 1, the discharge nozzle 3b of the syringe 3 is brought into close contact with the liquid surface of the molten metal 1 within the molten metal storage tank 6. Then, with the cover 9 of the bypass path 3d of the syringe 3 closed, the shaft 4 is pulled upward. As a result, the pressure in the syringe 3 decreases, and the syringe 3 draws the molten metal 1 inside (step 1).

Next, the molten metal discharging device 100 including the syringe 3, the shaft 4, and the temperature control unit 7 moves using the three-axis movement mechanism (not shown), and positions the discharge nozzle 3b above the component 2 such as a semiconductor device (step 2).

Next, as shown in FIG. 2, with the cover 9 of the bypass path 3d of the syringe 3 opened, the shaft 4 is pushed down to discharge the molten metal 1 from the discharge nozzle 3b onto the component 2 (step 3). Note that the cover 9 of the bypass path may be opened throughout the entire time when the shaft 4 is pushed down, or the cover 9 may be opened only during a part of the time when the shaft 4 is pushed down. Finally, the discharged molten metal 1 is cooled and solidified (step 4). Thereby, the component 2 and other members can be joined by the molten metal 1.

As explained above, in the present embodiment, a bypass path 3d is provided that connects the opening 3c, which is different from the discharge nozzle 3b, and the storage section 3a. Opening the cover 9 provided at the opening 3c in the molten metal discharge operation allows a certain amount of the molten metal 1 to flow into the bypass path 3d while discharging the molten metal 1 from the discharge nozzle 3b. This makes it possible to discharge the molten metal 1 with a volume smaller than the amount of change in volume in the syringe 3 due to the downward movement of the shaft 4, to control the discharge amount of the molten metal 1 with high accuracy.

Note that it is also possible to control the discharge amount of the molten metal 1 from the discharge nozzle 3b by discharging the molten metal 1 that has passed through the bypass path 3d to the outside and adjusting the flow rate with a flow rate control valve. However, the control accuracy of the discharge amount decreases due to the heat resistance of the flow rate control valve and thermal expansion at high temperatures. In contrast, in the present embodiment, the opening 3c is positioned above the upper surface of the molten metal 1 inside the syringe 3. Therefore, the molten metal 1 that has passed through the bypass path 3d is not discharged to the outside from the opening 3c, so that the above problem does not occur.

Furthermore, the control unit 10 individually controls the sliding of the shaft 4, and the opening and closing of the cover 9. This makes it possible to open the cover 9 depending on the amount of the molten metal 1 to be discharged and allow the molten metal 1 to flow into the bypass path 3d for any period of time. For example, instead of opening the cover 9 throughout the entire time of the molten metal discharge operation, the cover 9 can be opened only during a part of the time of the molten metal discharge operation. Thereby, the discharge amount of the molten metal 1 can be controlled with high accuracy.

### Embodiment 2

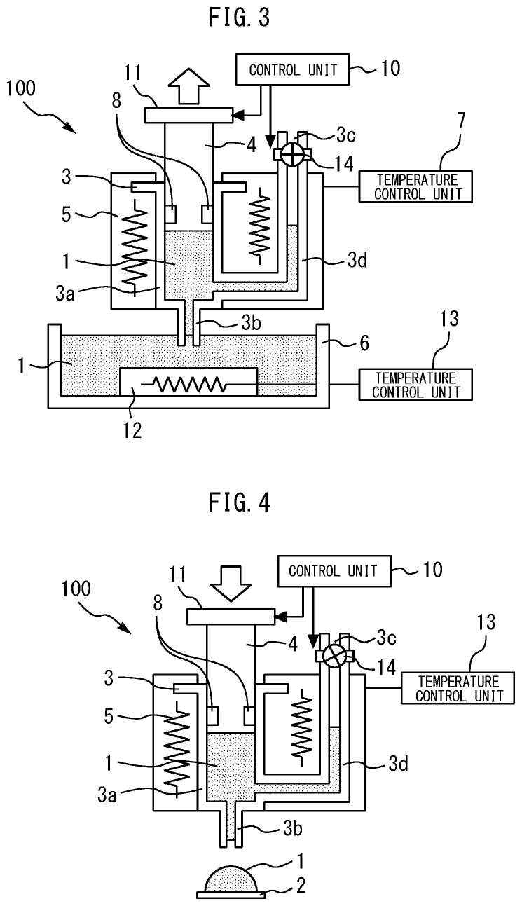

FIG. 3 is a cross sectional view showing the molten metal suction operation of the molten metal discharging device according to Embodiment 2. FIG. 4 is a cross sectional view showing the molten metal discharge operation of the molten metal discharging device according to Embodiment 2.

In the present embodiment, a flow rate control valve 14 is provided in place of the cover 9 at the opening 3c of the bypass path 3d. The flow rate control valve 14 continuously adjusts the flow rate of air discharged from the inside of the bypass path 3d to the outside. The flow rate control valve 14 is, for example, a diaphragm valve or a butterfly valve. The other components are the same as those in Embodiment 1.

Closing the flow rate control valve 14 in discharge of the molten metal 1 increases the pressure of the air inside the bypass path 3d with the liquid level rise in the bypass path 3d, which acts as a resistance to the liquid level rise in the bypass path 3d. In contrast, opening the flow rate control valve 14 allows a certain amount of the molten metal 1 to flow into the bypass path 3d while the molten metal 1 is discharged from the discharge nozzle 3b. Then, opening the flow rate control valve 14 while adjusting the flow rate lets out the pressurized air and controls the speed of the liquid level rise in the bypass path 3d. This makes it possible to finely adjust the flow rate of the molten metal 1 flowing into the bypass path 3d to allow control of the discharge amount of the molten metal 1 with even higher accuracy.

### REFERENCE SIGNS LIST

1 molten metal; 3 syringe; 3a storage section; 3b discharge nozzle; 3c opening; 3d bypass path; 4 shaft; 5 heater; 9 cover; 14 flow rate control valve; 100 molten metal discharging device

1. A molten metal discharging device comprising:
a syringe including a storage section that stores molten metal, a discharge nozzle that discharges the molten metal stored in the storage section, an opening different from the discharge nozzle, and a bypass path that connects the opening and the storage section and through which the molten metal flows;
a heater provided around the syringe and heating the molten metal to keep the molten metal in a molten state;
a shaft sliding inside the syringe to press the molten metal stored within the storage section; and
a cover provided on the opening, opening and closing,
wherein the opening is positioned above an upper surface of the molten metal inside the syringe.

2. The molten metal discharging device according to claim 1, wherein opening and closing of the cover and sliding of the shaft are individually controlled.

3. The molten metal discharging device according to claim 1, wherein the cover is a flow rate control valve adjusting a flow rate of air discharged from an inside of the bypass path to outside.

4. The molten metal discharging device according to claim 1, wherein the molten metal passed through the bypass path is not discharged to outside from the opening.

5. A molten metal discharging method using the molten metal discharging device according to claim 1, comprising:
bringing the discharge nozzle of the syringe into close contact with a liquid surface of the molten metal within a molten metal storage tank and pulling the shaft upward with the cover closed to draw the molten metal inside the syringe; and
positioning the discharge nozzle above a component and pushing down the shaft with the cover opened to discharge the molten metal from the discharge nozzle onto the component.

6. The molten metal discharging method according to claim 5, wherein the cover is opened only during a part of time when the shaft is pushed down.
